(19) United States
(12) Patent Application Publication
(10) Pub. No.: US 2026/0352065 A1
(43) Pub. Date: Nov. 5, 2026

(54) DEFORMATION CORRECTION DEVICE

(71) Applicant: THE INSTITUTE OF OPTICS AND ELECTRONICS, THE CHINESE ACADEMY OF SCIENCES, Chengdu (CN)

(72) Inventors: Xiangang Luo, Chengdu (CN); Minggang Liu, Chengdu (CN); Chengwenli Li, Chengdu (CN); Yunqing Sun, Chengdu (CN); Zhipeng Wu, Chengdu (CN); Xiaoan Chen, Chengdu (CN); Changtao Wang, Chengdu (CN)

(21) Appl. No.: 19/665,101

(22) Filed: May 1, 2026

Related U.S. Application Data
(63) Continuation-in-part of application No. PCT/CN2023/139565, filed on Dec. 18, 2023.

(30) Foreign Application Priority Data
Nov. 6, 2023 (CN) 202311470184.3

(51) Int. Cl. H02K 7/14; F16C 11/04; H02K 7/00

(52) U.S. Cl. CPC H02K 7/14; F16C 11/04; H02K 7/003

(57) ABSTRACT

A deformation correction device includes a double-layer hinge mechanism in a vertically-stacked form, each layer of the hinge mechanism comprising sixteen correction units which are symmetrically arranged at four quadrants for controlling deformation of a mask; and a flow guide structure, disposed below the double-layer hinge mechanism, wherein a central region of the flow guide structure is reserved as a mask mounting area, and wherein when an airflow blows the flow guide structure, the flow guide structure redirects the airflow peripherally.

### CROSS-REFERENCE TO RELATED APPLICATIONS

The present disclosure is a Continuation-In-Part Application of PCT Application No. PCT/CN2023/139565 filed on Dec. 18, 2023, which claims priorities to Chinese Patent Application No. 202311470184.3, filed with the China National Intellectual Property Administration on Nov. 06, 2023 and entitled "DEFORMATION CORRECTION DEVICE", the entire content of which is incorporated herein by reference.

### TECHNICAL FIELD

The present disclosure relates to the field of optomechanical equipment technology, and in particular to a deformation correction device.

### BACKGROUND

The micro-nano manufacturing technology aims to further scale down the minimum feature sizes of micro-nano structures while improving the product yield. This imposes stricter requirements on the dimensional accuracy and linewidths of patterns on masks.

As the requirements for mask linewidths and positional alignment in photolithography processes become increasingly stringent, the control requirements for these parameters are also very stringent. Masks are affected by factors such as processing and clamping differences and ambient temperatures (inconsistencies in processing, transportation, and experimental temperatures), causing mask patterns to deform randomly within a range of 1 ppm. At present, an active control method is usually adopted, that is, to actively control the deformation of a mask by applying controllable force to the edge of the mask or applying controllable energy to the mask to offset the deformation caused by the mask process, thereby actively regulating the mask's inherent deformation.

The main disadvantages of related technologies are as follows: First, for mask correction, cylinders are generally used as power input units, which suffer from inadequate force resolution and poor repeatability, failing to meet the precision control requirements of masks; second, sixteen units are generally used for mask correction, resulting in suboptimal correction accuracy and correction force; and third, the hinge mechanism is susceptible to low-frequency resonance caused by multipoint vortex generation when exposed to airflow from the environmental control system's gas shower. Additionally, particulate matter generated during equipment operation may fall above the mask onto the wafer, adversely affecting subsequent pattern transfer.

### SUMMARY

In view of the above problems, the present disclosure provides a deformation correction device to solve the above technical problems.

In a first aspect, the present disclosure provides a deformation correction device, including: a stacked double-layer hinge mechanism, each layer of the hinge mechanism including sixteen correction units which are symmetrically arranged at four quadrants for controlling the deformation of a mask; and a flow guide structure, which is disposed below the double-layer hinge mechanism, wherein a central region of the flow guide structure is reserved as a mask mounting area. When an airflow blows the flow guide structure, the flow guide structure redirects the airflow peripherally.

According to embodiments of the present disclosure, the correction unit includes a drive motor, a fixing plate, a guide ball head, a ball head stopper, a hinge unit, a force sensor, a compensation hinge, and a flexible block. The output shaft of the drive motor passes through the fixing plate to connect the guide ball head. The hinge unit is fixedly connected to the ball head stopper, and the guide ball head is installed between the hinge unit and the ball head stopper. The hinge unit includes a short side perpendicular to the force output direction of the drive motor and a long side parallel to the force output direction of the drive motor. For the short side, its upper end is fixed to the ball head stopper, and its lower end is connected to one end of the long side. The force sensor, the compensation hinge, and the flexible block are sequentially connected to extend from the other end of the long side. The force sensor measures a force applied to the mask and provides feedback to the drive motor.

According to embodiments of the present disclosure, the hinge mechanism further includes a base plate. The correction unit is fixed to the base plate via a fixing plate. The short side of the hinge unit passes downward through the central region of the base plate. Specifically, the four corners of the base plate of the upper hinge mechanism are fixed to the base plate of the lower hinge mechanism by screws. Upper correction units and lower correction units in the same direction are staggered. Compared with the lower correction units, the upper correction units are closer to the central region of the base plate, and have smaller dimensions.

According to embodiments of the present disclosure, the drive motor is a piezoelectric motor.

According to embodiments of the present disclosure, a groove perpendicular to the force output direction of the drive motor is provided in the ball head stopper and the hinge unit, the guide ball head is engaged in the groove, and the groove has a trapezoid cross section.

According to embodiments of the present disclosure, the hinge mechanism further includes a hinge lapping member. The hinge unit passes through the hinge lapping member, and is fixed to the base plate by screws.

According to embodiments of the present disclosure, the ratio of the long side to the short side of the hinge unit is 2:1.

According to embodiments of the present disclosure, the flow guide structure includes fixing parts, a guide plate, and a first sealing ring. The fixing parts are arranged at the four corners of the guide plate to fix the flow guide structure to the lower position of the double-layer hinge mechanism. The guide plate is a stainless-steel thin plate, and the gap between it and the double-layer hinge mechanism is sealed by the first sealing ring.

According to embodiments of the present disclosure, base plate lapping pads are provided at screw holes at the four corners of the base plate of the lower hinge mechanism.

According to embodiments of the present disclosure, the outer edge of the base plate of the lower hinge mechanism is surrounded by a second sealing ring to seal the gap between the base plate and a lithography apparatus when the base plate is installed in the lithography apparatus.

At least one technical solution adopted in the embodiments of the present disclosure can achieve the following beneficial effects.

The deformation correction device applies compressive forces to the side wall of the mask held by a vacuum chuck. The lateral force applied to the side wall of the mask propagates to the central region, inducing controlled deformation in the pattern area, thereby achieving the operational objective of the device. Specifically, the device has thirty-two correction units, with eight correction units arranged on each side, and enable compensation for diverse deformation modes of the mask. The displacement correction of the pattern area is generally at nanometer-scale magnitudes. A double-layer stacked hinge mechanism accommodates multiple configurations compact sixteen correction units, standard sixteen correction units, and thirty-two correction units to adapt to correction tests under varying operational conditions.

The device has a flow guide structure. When the deformation correction device is affected by the environmental control system's gas shower, the flow guide structure redirects the bottom-top airflow dispersing radially outward, such that the airflow does not directly act on the hinge mechanism, allowing the impact of the airflow on the mask to attenuate within a certain time, and accelerating attenuation of airflow-induced disturbances on the mask, mitigating flow-induced vibration, thereby reducing the pattern jitter caused by external vibration and improving the processing precision.

### BRIEF DESCRIPTION OF DRAWINGS

In order to have a more complete understanding of the present disclosure and its advantages, the following description is made with reference to drawings, specifically:

FIG. 1A is a schematic diagram of a deformation correction device according to an embodiment of the present disclosure;

FIG. 1B is a schematic exploded view of a deformation correction device according to an embodiment of the present disclosure;

FIG. 2A is a schematic diagram of mask correction force application points according to an embodiment of the present disclosure;

FIG. 2B is a schematic diagram of the bottom of a deformation correction device according to an embodiment of the present disclosure;

FIG. 3A is a schematic front view of correction units according to an embodiment of the present disclosure;

FIG. 3B is a schematic side view of correction units according to an embodiment of the present disclosure;

FIG. 4 is a schematic diagram of a flow guide structure according to an embodiment of the present disclosure; and

FIG. 5 is a schematic diagram of an airflow guidance according to an embodiment of the present disclosure.

Reference numerals in the drawings are as follows:
1: upper correction unit;
2: upper base plate;
3: lower correction unit;
4: lower base plate;
41: base plate lapping pad;
42: second sealing ring;
5: flow guide structure;
6: drive motor;
7: fixing plate;
8: guide ball head;
9: ball head stopper;
10: hinge lapping member;
11: hinge unit;
12: force sensor;
13: compensation hinge;
14: flexible block;
15: fixing part;
16: guide plate;
17: first sealing ring;
18: mask; and
21: screw hole.

### DETAILED DESCRIPTION OF THE EMBODIMENTS

Embodiments of the present disclosure are described below with reference to the drawings. However, it should be understood that these descriptions are merely exemplary and are not intended to limit the scope of the present disclosure. In the following detailed description, for ease of explanation, many specific details are set forth to provide a comprehensive understanding of the embodiments of the present disclosure. However, it is obvious that one or more embodiments can also be implemented without these specific details. In addition, well-known structures and techniques are omitted in the following description to avoid unnecessarily obscuring the concepts of the present disclosure.

The terms used herein are only for describing specific embodiments and are not intended to limit the present disclosure. The terms "include" and "including" used herein indicate the presence of a feature, step, operation, and/or component, but do not exclude the presence or addition of one or more other features, steps, operations, or components.

All terms used herein (including technical and scientific terms) have the meanings generally understood by those skilled in the art unless otherwise defined. It should be noted that the terms used herein should be interpreted as having meanings consistent with the context of this specification and should not be interpreted in an idealized or overly rigid manner.

An embodiment of the present disclosure provides a deformation correction device, including a double-layer hinge mechanism and a flow guide structure 5. The double-layer hinge mechanism is in a vertically-stacked form, each layer of the hinge mechanism including sixteen correction units which are symmetrically arranged at four quadrants, that is, four correction units arranged in each direction of each layer of the hinge mechanism, eight correction units symmetrically arranged at each quadrant for controlling the deformation of a mask. The flow guide structure 5 is disposed below the double-layer hinge mechanism, with its central region reserved for mask mounting. When airflow blows the flow guide structure, the flow guide structure radially disperses the airflow toward peripheral regions.

The double-layer hinge mechanism employs a stacked configuration of thirty-two correction units to achieve thirty-two corrections of the mask 18, thereby increasing the density of the correction units and improving the correction precision. Additionally, this device can provide dual-mode two levels of deformation correction capability. The compact stacked double-layer design integrates thirty-two correction units within limited space, making the device more compact.

The deformation correction device applies compressive forces to the side wall of the mask held by a vacuum chuck, the lateral force applied to the side wall of the mask 18 propagates to the central region, and the mask pattern area deforms under the effect of the force, thereby achieving the operational objective of the device. When the mask is under operational state, a gas shower of a lithography apparatus purges particulate contaminants from the air. the flow guide structure redirects the bottom-top airflow dispersing radially outward, such that the airflow does not directly act on the hinge mechanism, allowing the impact of the airflow on the mask to attenuate within a certain time, and accelerating attenuation of airflow-induced disturbances on the mask, mitigating flow-induced vibration, thereby reducing the pattern jitter caused by external vibration and improving the processing precision. Without the flow guide structure 5, the airflow in the gas shower will pass through the complex hinge mechanism, making the hinge mechanism unstable.

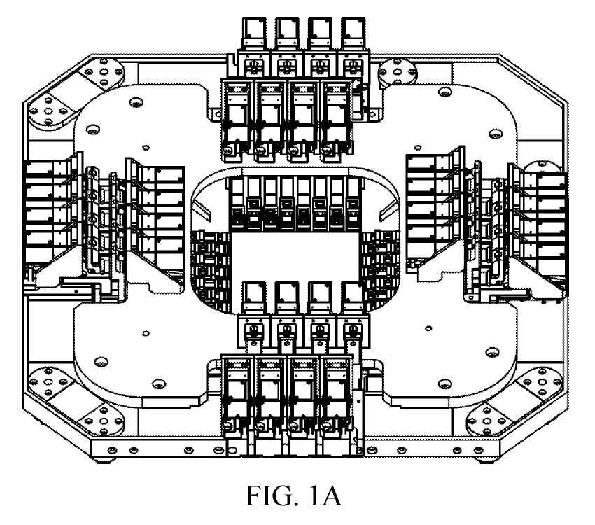

As shown in FIGS. 1A and 1B, in this embodiment, in order to achieve high-precision position and shape error compensation and correction, as well as multi-point and multi-region independent correction of the mask thirty-two correction units are evenly distributed around the mask 18. After the mask 18 is held by a chuck, each correction unit can act independently to perform the region error compensation and correction. The double-layer hinge mechanism is in a vertically-stacked form, each layer of the hinge mechanism including sixteen correction units (1 and 3 in the figures). This arrangement provides a layout of eight correction units on one side of the mask 18, doubling the correction precision of the mask 18 while providing the force required for correcting higher-order pattern deformations. The upper and lower hinge mechanisms adopt similar correction unit designs, but the outer-ring correction units are longer than the inner-ring correction units, so that the coaxial exposure light path will not be blocked by the correction units.

As shown in FIG. 1B, both the upper and lower hinge mechanisms include a base plate. The four corners of the upper base plate 2 of the upper hinge mechanism are fixed to the lower base plate 4 of the lower hinge mechanism by screws. Specifically, the screws are fixed to the lower base plate 4 through holes 21 at the four corners of the upper base plate 2. The upper correction units 1 is fixed to the upper base plate 2 by a fixing plate 7, and the lower correction units 3 is fixed to the lower base plate 4 by the fixing plate 7. The flow guide structure 5 is mounted on the lower base plate 4 by screws. Specifically, the screws are fixed to the bottom of the lower base plate 4 through holes drilled at the four corners of the flow guide structure 5. The above-mentioned three-layer plate structure jointly form a deformation correction device for the mask 18. In practical applications, the lower base plate 4 is assembled onto a main base plate (not shown in the figures) of the lithography apparatus by screws or other means through the holes at its four corners. The outer edge of the lower base plate 4 is surrounded by a second sealing ring 42 to seal the gap between the lower base plate 4 and the main base plate of the lithography apparatus. This prevents particles carried by the external gas or particles generated during the operation of the lithography apparatus from entering the confined space between the lower base plate 4 and the main base plate of the lithography apparatus. At the screw holes at the four corners of the lower base plate 4, base plate lapping pads 41 are provided to eliminate processing errors of the main base plate of the lithography apparatus or the deformation correction device during assembly, or to ensure assembly parallelism between the main base plate of the lithography apparatus and the deformation correction device.

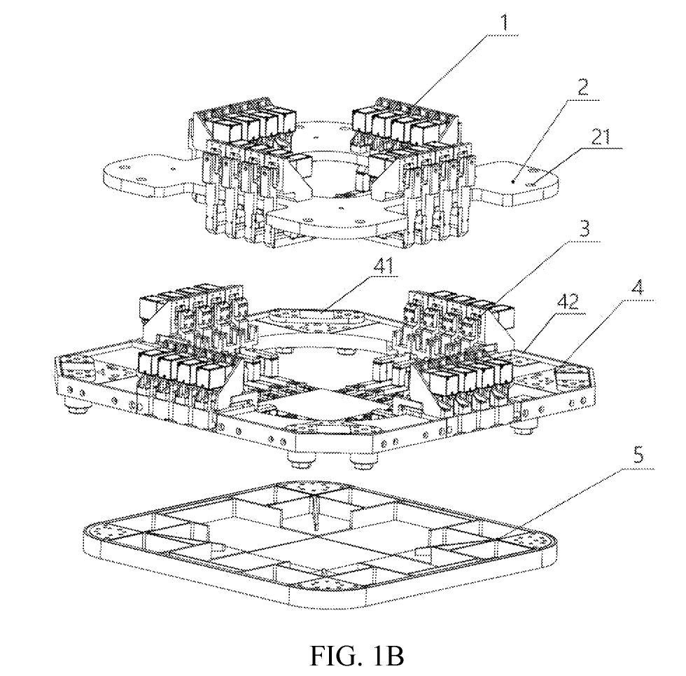

As shown in FIG. 2A, four mask deformation correction units and eight mask deformation correction units are drawn on two sides of the same mask 18 to illustrate why the mask deformation correction precision is improved. When four correction units are set on one side, the mask 18 has only four force bearing points. When eight correction units are set on one side, the mask 18 has eight force bearing points. Eight correction units can control the deformation of regions between the force bearing points of the mask more precisely.

Optionally, the number of correction units on one side is not limited to eight. Other numbers are also feasible. Selection based on actual needs is allowed.

As shown in FIG. 2B, the upper correction units 1 and the lower correction units 3 in the same direction are staggered. Compared with the lower correction units 3, the upper correction units 1 are closer to the central region of the base plate, and have smaller dimensions. When the upper and lower correction units perform deformation correction separately, the upper correction units 1, due to their small size, can independently adapt to the shape and weight requirements for a posture adjustment device of the mask 18, while the lower correction units 3, due to their large size, can avoid the large lens barrel assembly composed of coaxial, four-level lighting, and alignment components.

The upper and lower hinge mechanisms can be separated and used independently to form two sets of sixteen correction units, and can also be combined to form thirty-two correction units for use. For example, for deformation correction of a mask 18 with a low deformation correction resolution requirement, the upper sixteen correction units 1 or the lower sixteen correction units 3 can be selected for use. When it is necessary to improve the correction capability (including improving the correction accuracy and outputting a greater force to the mask 18), thirty-two correction units can be used to perform deformation correction for a mask 18 with a high deformation correction resolution. Different combinations of sixteen correction units in the upper layer and sixteen correction units in the lower layer are used to perform correction tests for different working conditions, to improve the adaptability of the correction units to the device.

During the assembly process, after the assembly of the two separate sets of sixteen correction units is completed, the installation of the thirty-two correction units can be installed as a whole. The two sets of sixteen correction units can be assembled synchronously to improve the efficiency of mechanical assembly.

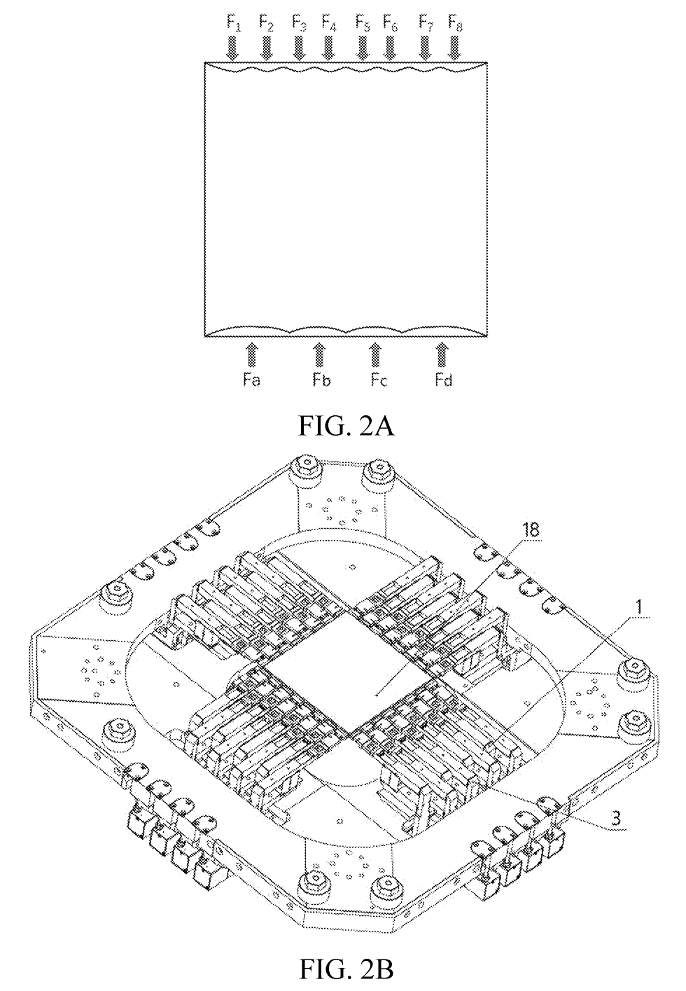

As shown in FIG. 3A, both the upper correction units 1 and the lower correction units 3 include: a drive motor 6, a fixing plate 7, a guide ball head 8, a ball head stopper 9, a hinge unit 11, a force sensor 12, a compensation hinge 13, and a flexible block 14. The output shaft of the drive motor 6 passes through the fixing plate 7 and is connected to the guide ball head 8. The hinge unit 11 and the ball head stopper 9 are fixedly connected, and the guide ball head 8 is installed between the hinge unit 11 and the ball head stopper 9. The hinge unit 11 includes a short side perpendicular to the force output direction of the drive motor 6 and a long side parallel to the force output direction of the drive motor 6. For the short side, its upper end is fixed to the ball head stopper 9, and its lower end is connected to one end of the long side. The force sensor 12, the compensation hinge 13, and the flexible block 14 are sequentially connected to extend from the other end of the long side. The force sensor 12 measures the force on the mask 18 and feeds it back to the drive motor 6.

In this embodiment, the drive motor 6 is a piezoelectric motor. The piezoelectric motor can be used in combination with the hinge mechanism to accurately adjust the deformation of the pattern area. The regional adjustment method is adopted to correct mask deformation errors step by step. In traditional deformation correction systems, cylinders are used to provide the input force, but the resolution of the force output by these cylinders is about 1 N. Moreover, for cylinders outputting larger force, the resolution of the force output by them tends to be lower. In other words, the magnitude of the output force is inversely proportional to the resolution of the output force. As a result, cylinders cannot meet the requirements for large correction stroke and high correction precision at the same time. When a piezoelectric motor outputs the same force as that output by a cylinder, the resolution of the force output by the piezoelectric motor can reach 0.15 N, while the resolution of the force output by the cylinder is only 1 N. Compared to the cylinder, the piezoelectric motor can improve the resolution of the compressive force on the system mask side wall, thereby improving the resolution of pattern correction for the mask 18.

As shown in FIG. 3B, a groove perpendicular to the force output direction of the drive motor 6 is provided in the ball head stopper 9 and the hinge unit 11, the guide ball head 8 is engaged in the groove, and the groove has a trapezoid cross section. During the push-pull process of the drive motor 6, the guide ball head 8 is bidirectionally compressed by the hinge unit 11 and the ball head stopper 9. The guide ball head 8 can slide vertically in the groove as shown in FIG. 3B, to make real-time adjustments to prevent the output shaft of the drive motor 6 from being damaged by the vertical force acting on it when it pushes or pulls the hinge unit 11. In other words, the vertical sliding of the guide ball head 8 in the groove as shown in FIG. 3B allows the output shaft of the drive motor 6 to make adaptive adjustments to the vertical force acting on it.

A mounting region is reserved for the mask 18 in the central region of both the upper base plate 2 and the lower base plate 4. In each correction unit, the short side of the hinge unit 11 passes downward through the central regions of the base plate 2 and the base plate 4, making the flexible block 14 connected to the long side of the hinge unit 11 face the mask 18 located in the central region of the base plate 4. The hinge unit 11 is designed with multiple sets of flexible thin-walled structures, and the ratio of the long side to the short side is designed to be 2:1 by applying the lever magnification principle (as shown in FIG. 3A, the long side is shown in the horizontal direction and the short side is shown in the vertical direction). This design amplifies the output force by two times and reduces the displacement by 0.5 times, thereby providing greater compressive force on the side wall of the mask 18 and correcting larger deformation sizes. The hinge unit 11 transmits the force output by the drive motor 6 to the mask 18 through the flexible block 14, making the pattern area of the mask 18 distort, offset, shift, or generate other deformations. Before exposure, the deformation correction device corrects deformation errors of the mask 18 caused by processing, thermal deformation, and other reasons, to ensure that the pattern is corrected to the expected shape. The flexible block 14 contacts the mask 18 in a small area to avoid the line contact force, reduce installation and adjustment difficulties, and improve the compressive efficiency. When the upper correction units 1 and the lower correction units 3 are in the initial state, the output shaft of the drive motor 6 is perpendicular to the short side mounting surface of the hinge unit 11. During operation, the upper correction units 1 and the lower correction units 3 are in a lever state, that is, the upper correction units 1 and the lower correction units 3 rotate. Therefore, during this process, the output shaft of the drive motor 6 needs to adaptively adjust its posture through the guide ball head 8 to protect it against the excessive force in the vertical direction. The hinge unit 11 is fixedly connected to the mounting base plate 2 or 4 by screws that penetrate through the hinge lapping member 10. The hinge unit 11 is flexible, and can rotate within a small range. The hinge lapping member 10 is used to adjust the flatness of the mounting base plate 2 or 4 and the hinge unit 11. The drive motor 6 is used to provide input force for the correction units. The force sensor 12 measures the force applied to the side wall of the mask 18, and implements a closed-loop design solution with the drive motor 6.

The hinge unit 11 amplifies the input force according to the lever principle. The force sensor 12, installed near the force bearing position of the mask 18, online collects and feeds back the end force, and forms a force closed-loop with the drive motor 6, realizing precise control of the compressive force on the mask 18. The force sensor 12, made of alloy steel, collects force data in a micro-deformation manner. The hinge unit 11 deflects slightly at the position where the side wall of the mask 18 is compressed, resulting in a deviation between the force measured by the force sensor 12 and the actual force. The deflection of the force sensor 12 can be reversely compensated by the compensation hinge 13 designed through simulation. The flexible block 14, as the end of the correction units, is attached to the side wall of the mask 18. The contact surface is a Φ2 region and directly contacts the mask 18. This design reduces the contact surface, and adaptively adjusts the residual deflecting force to avoid uneven contact between the flexible block 14 and the mask 18.

The mounting surfaces of the fixing plate 7, ball head stopper 9, hinge unit 11, force sensor 12, compensation hinge 13, and hinge lapping member 10 need to be precisely ground after high-precision machining, to ensure that the contact force directions of the end of the correction units and the mask 18 are consistent during assembly, and to ensure the verticality of the force on the side wall of the mask. The hinge lapping member 10 adjusts the height and deflection angle of the flexible hinge unit 11 by grinding, to ensure that the flexible hinge unit 11 moves smoothly, the force output direction is perpendicular to the side wall of the mask 18, and the compressive position of the flexible block 14 at the end of the flexible hinge unit 11 is located at the centerline of the side wall of the mask 18. The overall structures of the upper correction units 1 and the lower correction units 3 are designed by adopting high-precision machining solutions and force deflection correction methods. This aims to achieve the highest possible verticality of the force applied to the side wall of the mask 18 during the design and assembly processes, and to minimize the difference between the force measured by the force sensor 12 and the actual force applied to the mask 18. Excessive component force in a non-perpendicular direction to the side wall of the mask 18 will cause structural damage, as well as tilting and deflection of the mask 18. The tilting and deflection of the mask will affect the measurement results of the force sensor 12, thereby affecting the deformation correction results of the deformation correction system.

The upper base plate 2 and the lower base plate 4 are designed to have a convex surface for adopting the grinding process to improve the large plane machining precision. The base plate lapping pads 41 are fixed to the base plate 4 by screws, and the four base plate lapping pads 41 need to be ground to equal thickness and flatness before assembly, to ensure the precision of installing them with the lithography apparatus during structural integration. Limit blocks for limiting the movement of the correction units along the base plate edges are fixed on the upper base plate 2 and the lower base plate 4. As shown in FIG. 1, the limit blocks limit positions of the four sets of correction units on the base plate edges from both sides.

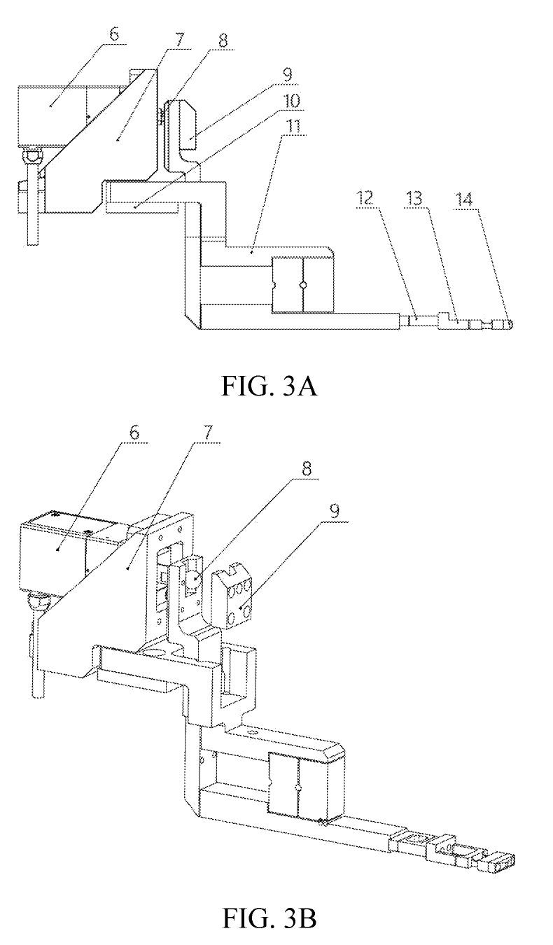

As shown in FIG. 4, the flow guide structure 5 includes fixing parts 15, a guide plate 16, and a first sealing ring 17. The fixing parts 15 are provided at the four corners of the guide plate 16 for fixing the flow guide structure 5 to the lower position of the double-layer hinge mechanism. Specifically, the flow guide structure 5 is connected to the lower base plate 4. To avoid occupying a large space, the guide plate 16 is made of stainless-steel sheet. Because the guide plate 16 is thin, reinforcing ribs shown in FIG. 4 are used to strengthen its mechanical properties. The first sealing ring 17 is used to seal the gap at the connection between the flow guide structure 5 and the double-layer hinge mechanism.

The flow guide structure 5 is installed on the lower surface of the lower base plate 4, and a mounting region is reserved in the middle for the mask 18. A transfer device for the mask 18 can smoothly transfer the mask to a mask chuck through the mounting region. During the operation of the lithography apparatus, particles may be generated above (such as an optical system) or below (such as a wafer stage) the mask. The flow guide structure 5 can prevent the particles above the mask 18 from falling onto wafers, and prevent the particles around the wafers from entering the exposure region. The ultimate effect of the flow guide structure is to prevent the particles from affecting the mask 18 and the wafers during the exposure process. The particles generated above the mask are caught by the flow guide structure 5, and will not fall onto the wafers. The particles generated under the mask 18 are carried by the airflow and dispersed around through the flow guide structure 5, preventing them from entering the space above the wafers. In this way, the impact of the particles on the exposure patterns is reduced.

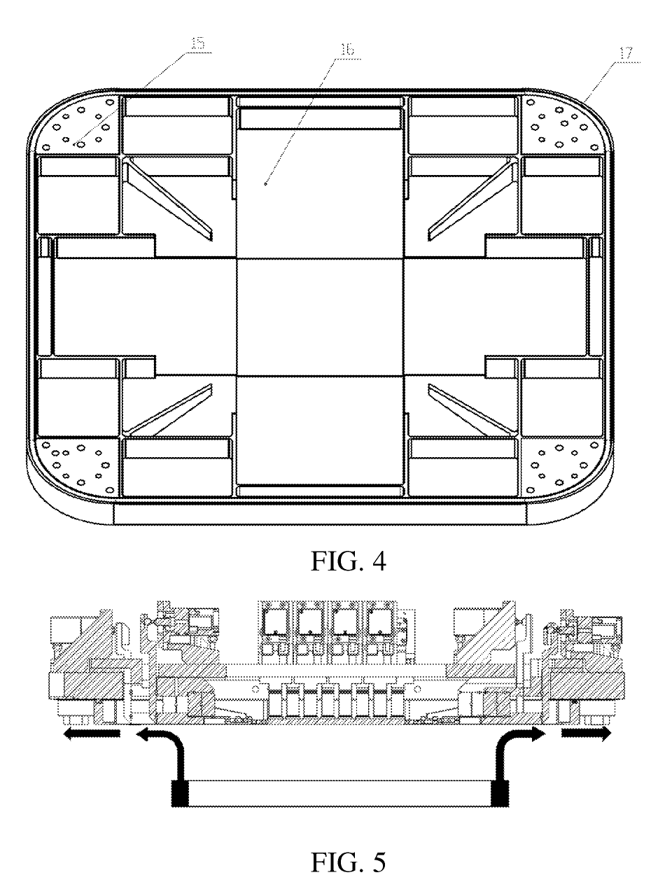

As shown in FIG. 5, the annular airflow blows in a bottom-up manner to the bottom surface of the deformation correction system. After contacting the bottom surface of the flow guide structure 5, the airflow forms a laminar flow and disperses around. Because the guide plate 16 is made of stainless-steel sheet, under the impact of the airflow, micro-vibration is generated behind the guide plate 16, making the mask 18 generate flow-induced vibration. Multiple small guide plates 16 are connected by welding to form the guide plate of the flow guide structure 5. This improves the modal properties, and increases the natural frequency of the entire flow guide structure 5. The flow guide structure 5 is used to control the flow-induced vibration of the mask 18, enabling the mask to reach a stable state in a short time when the vibration frequency exceeds 100 Hz.

The flow guide structure 5 is attached to the lower surface of the base plate 4, and does not contact the correction units, allowing it to perform its flow guide function without affecting the correction operation. The flow guide structure is fixed onto the base plate 4 from bottom to top, allowing it to be independently moved into and out of the device.

Those skilled in the art can understand that features described in various embodiments and/or claims of the present disclosure may be combined and/or integrated in a variety of ways, even if such combinations or integrations are not explicitly described in the present disclosure. In particular, the features described in the various embodiments and/or claims of the present disclosure may be combined and/or integrated in a variety of ways without departing from the spirit and teachings of the present disclosure. All these combinations and/or integrations fall within the scope of the present disclosure.

Although the present disclosure has been shown and described with reference to specific exemplary embodiments of the present disclosure, those skilled in the art should understand that various changes in form and detail may be made to the present disclosure without departing from the spirit and scope of the present disclosure as defined by the appended claims and their equivalents. Therefore, the scope of the present disclosure should not be limited to the preceding embodiments, but should be determined by the appended claims and their equivalents.

### INDUSTRIAL APPLICABILITY

The present disclosure provides a deformation correction device, including: a stacked double-layer hinge mechanism, each layer of the hinge mechanism including sixteen correction units which are symmetrically arranged at four quadrants for controlling the deformation of a mask; and a flow guide structure, which is provided below the double-layer hinge mechanism, wherein a central region of the flow guide structure is reserved as a mask mounting area. When an airflow blows the flow guide structure, the flow guide structure redirects the airflow peripherally. The device has a double-layer hinge mechanism including a total of thirty-two correction units for mask deformation correction, thereby increasing the density of the correction units and improving the correction precision. In the device, the flow guide structure is further designed for guiding the airflow to be dispersed, such that the airflow does not directly act on the hinge, thus allowing the impact of the airflow on the mask to attenuate within a certain time, and accelerating attenuation of airflow-induced disturbances on the mask, mitigating flow-induced vibration.

In addition, it can be understood that the deformation correction device disclosed in the present disclosure is reproducible and can be used in a variety of applications. For example, the deformation correction device disclosed in the present disclosure can be used in the field of optomechanical equipment technology.

1. A deformation correction device, comprising:
a stacked double-layer hinge mechanism, each layer of the hinge mechanism comprising sixteen correction units which are symmetrically arranged at four quadrants for controlling deformation of a mask; and
a flow guide structure, disposed below the double-layer hinge mechanism, wherein a central region of the flow guide structure is reserved as a mask mounting area, and wherein when an airflow blows the flow guide structure, the flow guide structure redirects the airflow peripherally.

2. The device according to claim 1, wherein the correction unit comprises:
a drive motor, a fixing plate, a guide ball head, a ball head stopper, a hinge unit, a force sensor, a compensation hinge, and a flexible block, wherein
an output shaft of the drive motor passes through the fixing plate to connect the guide ball head;
the hinge unit is fixedly connected to the ball head stopper, and the guide ball head is installed between the hinge unit and the ball head stopper;
the hinge unit comprises a short side perpendicular to a force output direction of the drive motor and a long side parallel to the force output direction of the drive motor; for the short side, its upper end is fixed to the ball head stopper, and its lower end is connected to one end of the long side; and
the force sensor, the compensation hinge, and the flexible block are sequentially connected to extend from the other end of the long side, and the force sensor measures a force applied to the mask and provides feedback to the drive motor.

3. The device according to claim 2, wherein the hinge mechanism further comprises:
a base plate, wherein the correction unit is fixed to the base plate via a fixing plate; the short side of the hinge unit passes downward through a central region of the base plate; and
four corners of the base plate of an upper hinge mechanism are fixed to the base plate of a lower hinge mechanism by screws, the upper correction units and the lower correction units in the same direction are staggered, and compared with the lower correction units, the upper correction units are closer to the center of the base plate, and have smaller dimensions.

4. The device according to claim 2, wherein the drive motor is a piezoelectric motor.

5. The device according to claim 2, wherein a groove perpendicular to the force output direction of the drive motor is provided in the ball head stopper and the hinge unit, the guide ball head is engaged in the grooves, and the grooves have trapezoid cross sections.

6. The device according to claim 3, wherein the hinge mechanism further comprises:
a hinge lapping member; and
the hinge unit passes through the hinge lapping member, and is fixed to the base plate by screws.

7. The device according to claim 2, wherein a ratio of the long side to the short side of the hinge unit is 2:1.

8. The device according to claim 1, wherein the flow guide structure comprises:
fixing parts, a guide plate, and a first sealing ring;
the fixing parts are arranged at the four corners of the guide plate to fix the flow guide structure to a lower position of the double-layer hinge mechanism; and
the guide plate is a stainless-steel thin plate, and a gap between the guide plate and the double-layer hinge mechanism is sealed by the first sealing ring.

9. The device according to claim 3, wherein base plate lapping pads are provided at screw holes at the four corners of the base plate of the lower hinge mechanism.

10. The device according to claim 3, wherein an outer edge of the base plate of the lower hinge mechanism is surrounded by a second sealing ring to seal a gap between the base plate and a lithography apparatus when the base plate is installed therein.
